(19) United States
(12) Patent Application Publication
(10) Pub. No.: US 2016/0150655 A1
(43) Pub. Date: May 26, 2016

(54) ELECTRONIC APPARATUS

(71) Applicant: DENSO CORPORATION, Kariya-city (JP)

(72) Inventors: Masayuki TAKENAKA, Kariya-city (JP); Norihisa IMAIZUMI, Kariya-city (JP); Toshihiro NAKAMURA, Kariya-city (JP)

(21) Appl. No.: 14/898,972

(22) PCT Filed: Jun. 17, 2014
(86) PCT No.: PCT/JP2014/003249

§ 371 Date: Dec. 16, 2015

(30) Foreign Application Priority Data
Jun. 18, 2013 (JP) 2013-127549
May 22, 2014 (JP) 2014-106198

(51) Int. Cl. H05K 5/00; H05K 7/20; H05K 5/02; H05K 1/02; H05K 1/11

(52) U.S. Cl. CPC H05K 5/0004; H05K 1/0204; H05K 1/115; H05K 5/0247; H05K 7/20409

(57) ABSTRACT

An electronic apparatus includes a board, an electronic component, a mold resin a rod-like connection terminal and a case. The board includes: a first surface; a second surface, which is opposite to the first surface; a wire pattern; and a through-hole having a metal member connected to the wire pattern. The electronic component mounted on the first surface of the board. The mold resin seals the electronic component on the first surface of the board. The rod-like connection terminal inserted into the through-hole from a distal end of the through-hole and electrically connected to the metal member. The case having a surface on which the connection terminal stands and accommodating the board on which the electronic component is mounted. The board is arranged such that the first surface on which the electronic component and the mold resin are arranged faces the surface of the case on which the connection terminal stands.

### CROSS REFERENCE TO RELATED APPLICATION

This application is based on Japanese Patent Application No. 2013-127549 filed on Jun. 18, 2013 and Japanese Patent Application No. 2014-106198 filed on May 22, 2014, the disclosure of which are incorporated herein by reference.

### TECHNICAL FIELD

The present disclosure relates to an electronic apparatus having a structure in that a connection terminal is inserted into a through-hole in a board on which an electronic component is mounted, and is electrically connected to a wiring pattern formed on the board via a solder joint in the through-hole.

### BACKGROUND ART

An electronic apparatus has hitherto been proposed, in Patent Literature 1, which has a structure in that a resin board with a circuit constituting component mounted thereon is encapsulated in a housing made of a mold resin, and an external connection terminal is connected to the inside of a through-hole formed in the resin board from an opposite side to the housing. Electrical connection to an external element is thus established via the external connection terminal by connecting the external connection terminal to the inside of the through-hole from the opposite side to the housing, i.e., from the opposite surface to the surface on which the circuit constituting component is mounted.

Patent Literature 2 discloses an electronic apparatus having a structure in that a connection terminal that is erected on a case is inserted into a through-hole formed in a board, and then is solder-joined in the through-hole, so that the connection terminal is electrically connected to a wiring pattern formed on the board. In this electrical device, the connection terminal has a curved portion in order to prevent stress resulting from thermal deformation of the board from being applied to the solder joint. The curved portion of the connection terminal allows the connection terminal to deform along the plane direction of the board to flexibly accommodate extension and contraction of the distance between both ends of the board resulting from thermal deformation of the board. Thus, stress application to the solder joint is prevented, and damage to the solder joint is reduced.

### PRIOR ART LITERATURES

### Patent Literature

Patent Literature 1: JP 5167354-A

Patent Literature 2: JP H11-26955-A

### SUMMARY OF INVENTION

However, according to a structure in that an external connection terminal is connected to the inside of a through-hole from an opposite surface to a surface on which a circuit constituting component is mounted, as in the structure disclosed in Patent Literature 1, there is created a dead space by the height of the housing, which makes it impossible to make the electronic apparatus smaller. In particular, if a lead bending process is to be performed for the purpose of reducing stress on the external connection terminal, there will be even more dead space, which makes it impossible to make the electronic apparatus smaller. Also, the length of the external connection terminal, i.e., the distance from the opposite surface to the surface on which the circuit constituting component is mounted to the case on which the external connection terminal is erected is made short. There is thus a possibility that the external connection terminal is disconnected from the through-hole due to increased stress applied to the connection between the external connection terminal and the through-hole, and that connection reliability is lost.

On the other hand, a structure in that a curved portion is formed on a connection terminal, as in the structure disclosed in Patent Literature 2, requires a process step for forming the curved portion on the connection terminal.

A first object of the present disclosure is to provide an electronic apparatus having a structure that enables a reduction in size and can ensure connection reliability. A second object of the present disclosure is to provide an electronic apparatus having a structure that can mitigate stress applied to a solder joint between a connection terminal and a through-hole in a board and can reduce damage to the solder joint, without a process step for forming a curved portion on the connection terminal.

According to the electronic apparatus related to a first aspect of the present disclosure, the electronic apparatus includes: a board having a first surface, a second surface opposite to the first surface, a wiring pattern formed on the board, and a through-hole formed in the board and connected to the wiring pattern; an electronic component mounted on the first surface of the board; a mold resin encapsulating the electronic component on the first surface of the board; a rod-like connection terminal inserted into the through-hole from a distal end of the through-hole and electrically connected to the through-hole; and a case having a surface on which the connection terminal is erected and housing the board on which the electronic component is mounted. In addition, the board is arranged such that the first surface on which the electronic component and the mold resin are arranged faces the surface of the case on which the connection terminal is erected.

As described above, the surface on which the electronic component is mounted, i.e., the surface on which the mold resin is disposed is oriented to face the surface of the case on which the connection terminal is erected. Thus, no dead space by the height of the mold resin is formed. The electronic apparatus can accordingly have a structure that enables a reduction in size. Moreover, a certain length for the connection terminal can also be secured, so that stress applied to the connection between the connection terminal and the through-hole can be reduced, and connection reliability can be secured.

According to the electronic apparatus related to a second aspect of the present disclosure, the electronic apparatus includes: a board having a first surface, a second surface opposite to the first surface, a wiring pattern formed on the board, and a through-hole formed in the board and connected to the wiring pattern; an electronic component mounted on the first surface of the board; and a rod-like connection terminal inserted from into the through-hole a distal end of the through-hole and electrically connected to the through-hole via a solder joint. The board has, in a portion of the board where the through-hole is formed, a structure with reduced displacement such that an amount of thermal expansion and contraction in a thickness direction of the board is smaller as compared to portions other than the through-hole.

As described above, the board has, in the portion where the through-hole is formed, the structure with reduced displacement such that the amount of thermal expansion and contraction in the thickness direction of the board is smaller as compared to portions other than the through-hole. Accordingly, the stress along the axial direction of the connection terminal caused by the difference in thermal expansion coefficient between the solder joint in the through-hole and the board can be mitigated. Therefore, without having to perform a process step for forming a curved portion on the connection terminal, the stress applied to the solder joint between the connection terminal and the through-hole in the board can be mitigated, and damage to the solder joint can be reduced.

According to the electronic apparatus related to a third aspect of the present disclosure, the electronic apparatus includes: a board having a first surface, a second surface opposite to the first surface, a wiring pattern formed on the board, and a through-hole formed in the board and connected to the wiring pattern; an electronic component mounted on the first surface of the board; and a rod-like connection terminal inserted into the through-hole from a distal end of the through-hole and electrically connected to the through-hole via a solder joint. In addition, the board has, in a portion of the board where the through-hole is formed, an elastic deformable structure such that the board has a lower coefficient of elasticity in a thickness direction of the board as compared to portions other than the through-hole.

As described above, the elastic deformable structure such that the board has the lower coefficient of elasticity in its thickness direction is provided in the portion where the through-hole is formed. Therefore, the stress caused by the difference in thermal expansion coefficient between the solder joint and the board can be mitigated based on the deformation of the elastic deformable structure. Accordingly, without having to perform a process step for forming a curved portion on the connection terminal, the stress applied to the solder joint between the connection terminal and the through-hole in the board can be mitigated, and damage to the solder joint can be reduced.

### BRIEF DESCRIPTION OF DRAWINGS

The above and other objects, features and advantages of the present disclosure will become more apparent from the following detailed description made with reference to the accompanying drawings. In the drawings:

[FIG. 1]

FIG. 1 is a cross-sectional view of an electronic apparatus according to a first embodiment of the present disclosure;

[FIG. 2]

FIG. 2 is a perspective cross-sectional view along II-II of FIG. 1;

[FIG. 3]

FIG. 3 is a cross-sectional view of the vicinity of a connection terminal 65;

[FIG. 4]

FIG. 4 is a cross-sectional view of the vicinity of a connection terminal 65 in an electronic apparatus according to a second embodiment of the present disclosure;

[FIG. 5]

FIG. 5 is a cross-sectional view of the vicinity of a connection terminal 65 in an electronic apparatus according to a third embodiment of the present disclosure;

[FIG. 6]

FIG. 6 is a cross-sectional view of the vicinity of a connection terminal 65 in an electronic apparatus according to a fourth embodiment of the present disclosure;

[FIG. 7A]

FIG. 7A is a cross-sectional view showing one example of a process of producing a board 10 shown in FIG. 6;

[FIG. 7B]

FIG. 7B is a cross-sectional view showing one example of a process of producing the board 10 shown in FIG. 6;

[FIG. 8A]

FIG. 8A is a cross-sectional view showing another example of the process of producing the board 10 shown in FIG. 6;

[FIG. 8B]

FIG. 8B is a cross-sectional view showing still another example of the process of producing the board 10 shown in FIG. 6;

[FIG. 9]

FIG. 9 is a cross-sectional view of the vicinity of a connection terminal 65 in an electronic apparatus according to a fifth embodiment of the present disclosure;

[FIG. 10]

FIG. 10 is a cross-sectional view of the vicinity of a connection terminal 65 in an electronic apparatus according to a sixth embodiment of the present disclosure;

[FIG. 11]

FIG. 11 is a cross-sectional view of an electronic apparatus according to a seventh embodiment of the present disclosure; and

[FIG. 12]

FIG. 12 is a cross-sectional view of an electronic apparatus according to an eighth embodiment of the present disclosure.

### EMBODIMENTS FOR CARRYING OUT INVENTION

Hereinafter, embodiments of the present disclosure will be described with reference to the drawings. In the following description, elements that are identical or equivalent to each other in the respective embodiments are denoted with the same reference signs.

### First Embodiment

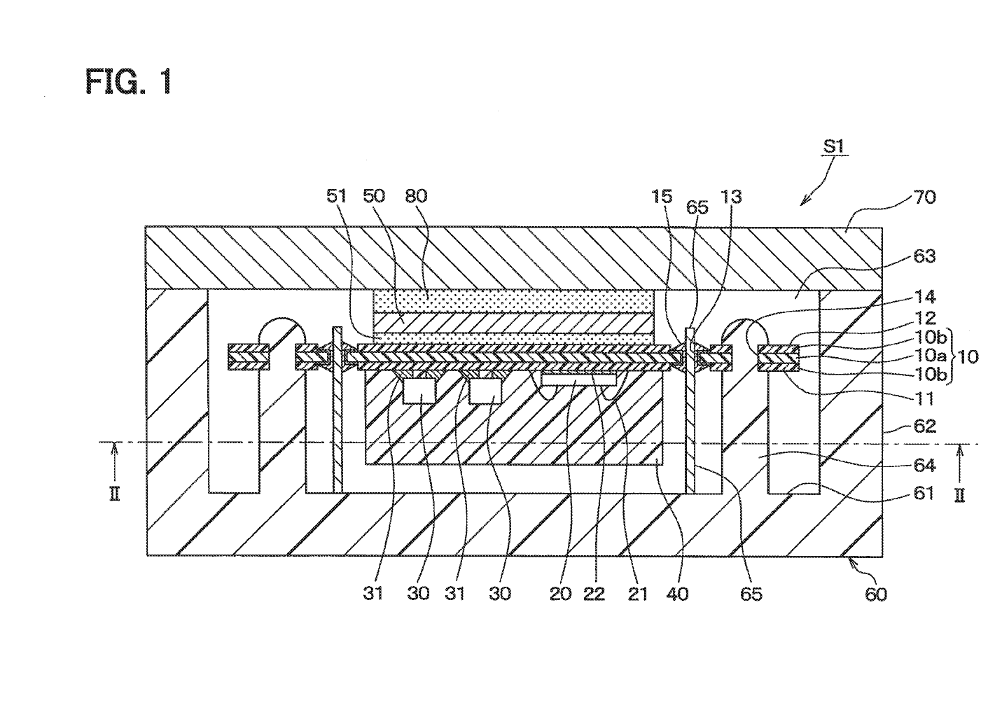

A general configuration of an electronic apparatus S1 according to a first embodiment of the present disclosure will be described with reference to FIGS. 1 to 3. The electronic apparatus S1 is mounted on a vehicle such as an automobile and is applied as an apparatus for driving various devices for the vehicle.

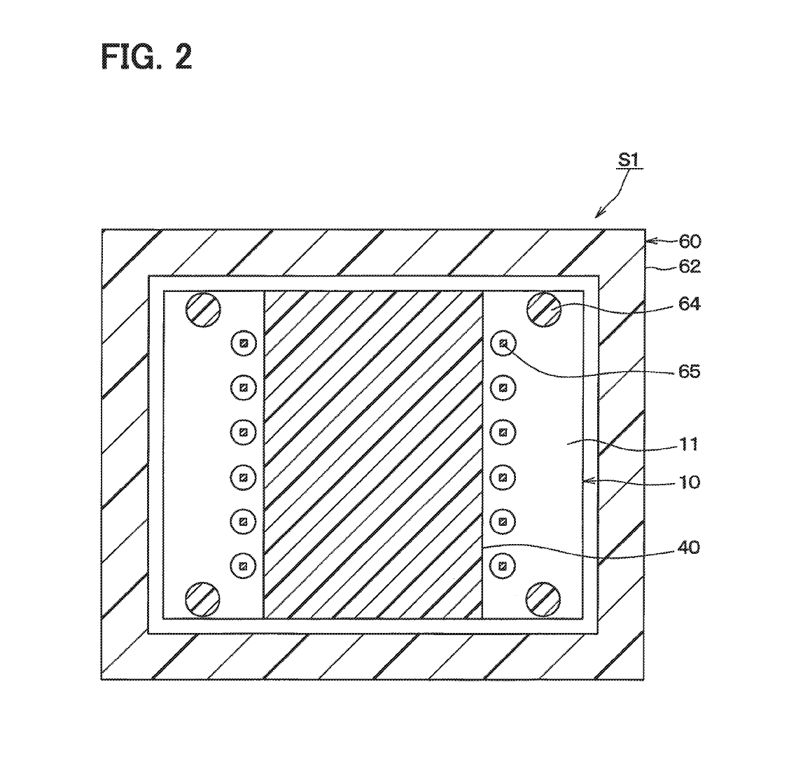

As shown in FIGS. 1 and 2, the electronic apparatus S1 is configured to include a board 10, electronic components 20 and 30, a mold resin 40, a heat sink 50, a case 60, a lid 70, a heat dissipating gel 80, and the like.

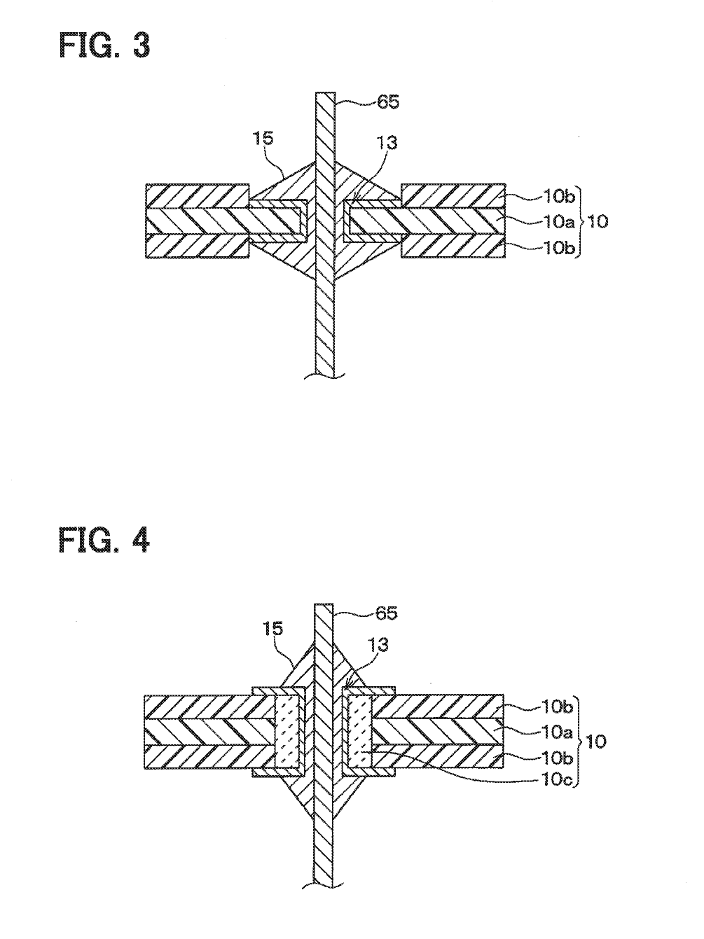

As shown in FIG. 1, the board 10 is formed of a plate-like member having a first surface 11 on which the electronic components 20 and 30 are mounted thereon and which is covered with the mold resin 40, and a second surface 12 opposite to the first surface 11. In this embodiment, the board 10 is formed as a plate-like member having a rectangular top plan shape as shown in FIG. 2, and is formed as a wiring board basically made of a resin such as an epoxy resin. More specifically, as shown in FIGS. 1 and 3, the board 10 is configured as a multilayer board having a core layer 10a made of a prepreg, which is a film-like glass cloth made of woven glass fiber and sealed with a thermosetting resin on both sides, and buildup layers 10b having the same configuration as the core layer 10a and disposed on both sides of the core layer 10a. An epoxy resin or the like is used as the thermosetting resin, which may contain fillers with excellent electrical insulation and heat dissipating properties, such as alumina or silica, as required. An inner wiring layer (not shown) is formed between the core layer 10a and each buildup layer 10b, and a surface wiring layer is formed on a surface of each buildup layer 10b. The inner wiring layer and the surface wiring layer configure a wiring pattern on the board 10.

The board 10 has a wiring pattern (not shown) formed thereon and configured with an inner wiring layer, a surface wiring layer, or the like. The wiring pattern extends to the outside of the mold resin 40, so that electrical connection with the electronic components 20 and 30 can be established via the wiring pattern. The board 10 has metal-plated or otherwise treated through-holes 13 formed on both sides in a longitudinal direction (a left and right direction of FIG. 1) and connected to the wiring pattern. The plurality of through-holes 13 are arranged along two opposite sides of the board 10, specifically, along both of the two shorter sides of the board 10. Electrical connection can be established between the wiring pattern and elements external to the board via the through-holes 13. In this embodiment, stress applied to solder joints 15 connected to connection terminals 65 to be described later is mitigated based on the structure of the through-holes 13, so that damage to the solder joints 15 can be reduced.

More specifically, as shown in FIG. 3, in this embodiment, in the portion where each through-hole 13 is formed, the size of the openings in both buildup layers 10b is made larger than the size of the opening in the core layer 10a. The structure is thus such that the opening edge of the core layer 10a is made closer to the connection terminals 65 than the opening edges of the buildup layers 10b. The structure is such that the through-holes 13 are configured by metal-plating the exposed surfaces of the core layer 10a including the inside of the opening, and the buildup layers 10b are not plated with metal. The through-holes 13 are configured with such a structure.

The board 10 thus configured is supported at four corners on the case 60. In this embodiment, fixture holes 14 that are through-holes are formed in the four corners of the board 10. Mechanical connection parts 64 protruding from a bottom surface 61 of the case 60 are fitted into the fixture holes. Thereafter, the distal ends of the mechanical connection parts 64 are heat-staked, so that the board 10 is supported on the case 60.

The electronic components 20 and 30 are electrically connected to the wiring pattern by being mounted on the board 10, and may be of any type such as surface-mounted components or through-hole-mounted components. In this embodiment, the electronic components 20 and 30 are described as a semiconductor element 20 and a passive element 30 as examples. Examples of the semiconductor element 20 include a microcomputer, a control element, and power elements with a high amount of heat generation such as an IGBT (Insulated Gate Bipolar Transistor) or a MOSFET (Metal-Oxide-Semiconductor Field-Effect Transistor). The semiconductor element 20 is connected to a land that connects to the wiring pattern of the board 10 or that is configured with a portion of the wiring pattern, with a bonding wire 21 and a die bonding material 22 such as solder. Examples of the passive element 30 include a chip resistance, a chip capacitor, a quartz crystal oscillator, and the like. This passive element 30 is connected to a land provided on the board 10 with a die bonding material 31 such as solder. With these configurations, the electronic components 20 and 30 are electrically connected to the wiring pattern formed on the board 10, and are electrically connectable to external elements via the through-holes 13 connected to the wiring pattern.

The mold resin 40 is configured with a thermosetting resin or the like such as an epoxy resin, and formed by a transfer molding or compression molding method with the use of a metal mold. In this embodiment, the first surface 11 of the board 10 is encapsulated in the mold resin 40, while the second surface 12 of the board 10 is not encapsulated in the mold resin 40 but is exposed, which is a so-called half-molded structure.

The mold resin 40 has a rectangular top plan shape as shown in FIG. 2, and is only formed inside the edges of two opposite sides of the board 10, specifically, both sides perpendicular to the longitudinal direction of the board 10 such that both of these sides are exposed. In other words, both ends in the longitudinal direction of the board 10 protrude out from the mold resin 40 and are exposed from the mold resin 40. The through-holes 13 are disposed in these portions exposed from the mold resin 40, so that electrical connection is possible between the wiring pattern formed on the board 10 and external elements via the through-holes 13. Since the board 10 is exposed along both sides from the mold resin 40, the four corners of the board 10 are exposed, and, as described above, the board 10 is supported on the case 60 in these portions exposed from the mold resin 40.

The heat sink 50 is made of a metal material having high heat conductivity, such as aluminum or copper, and is brought into close contact with the second surface 12 of the board 10 via a joint member 51. As the joint member 51, for example, a conductive adhesive containing metal filler, a conductive material such as a solder material, or an insulating material such as a heat dissipating gel or a heat dissipating sheet, can be used. The heat sink 50 acts to dissipate heat generated from the electronic components 20 and 30 and conducted from the second surface 12 of the board 10, and is made of a metal material having high heat conductivity, such as copper. If the semiconductor element 20 is configured with an IGBT or a MOSFET, in particular, since the IGBT and the MOSFET are heat-generating elements, a high amount of heat is generated. However, the heat is conducted to the heat sink 50, so that the semiconductor element 20 and the passive element 30 are prevented from being heated to a high temperature. In this embodiment, the heat sink 50 is thermally connected to the lid 70 via the heat dissipating gel 80, so that the heat conducted from the back surface of the board 10 is further conducted to the lid 70 through the heat dissipating gel 80 and is dissipated to the outside from the lid 70.

The case 60 is a rectangular casing that contains the board 10, which has the electronic components 20 and 30 mounted on the first surface 11 and encapsulated in the mold resin 40. In this embodiment, the case 60 is configured as a component that has side walls 62 covering the periphery of a bottom surface 61 to form a housing recess 63. The board 10 that has the electronic components 20 and 30 mounted thereon and encapsulated in the mold resin 40 is housed inside the housing recess 63 such that the first surface 11 faces the bottom surface 61. That is, the board 10 is housed inside the housing recess 63 such that the distal ends of the connection terminals 65 are inserted from the surface where the electronic components 20 and 30 are mounted and the mold resin 40 is disposed and the mold resin 40 is located between the distal end position and the proximal end position of the connection terminals 65.

The mechanical connection parts 64 that support the board 10 as described above are formed on the bottom surface 61 of the case 60. The mechanical connection parts 64 are stepped rod-like members that protrude vertically from the bottom surface 61 and have partly varying cross-sectional sizes. More specifically, before fixing the board 10 in position, the mechanical connection parts 64 have a bottom-side cross-sectional size larger than the fixture hole 14 formed in the board 10, and a distal end-side cross-sectional size substantially the same or somewhat smaller than the fixture hole 14. Having such sizes, the mechanical connection parts 64, as distal ends thereof are inserted into the fixture holes 14, retain the board 10 at the stepped portions between the distal end side and the bottom side. After the distal ends of the mechanical connection parts 64 are fitted into the fixture holes 14, the distal ends are heat-staked, whereby the portions protruding from the board 10 are increased in their cross-sectional size to be larger than the fixture holes 14. Thus, the board 10 is sandwiched and supported between these portions and the stepped portions.

The protruding amount of the mechanical connection parts 64 is set lower than the height of the side walls 62 so that the board 10 is accommodated in the housing recess 63 inside the distal ends of the side walls 62.

A plurality of rod-like connection terminals 65 are formed to be erected vertically to the bottom surface 61 of the case 60. The connection terminals 65 are aligned in two rows to match the arrangement of the through-holes 13 formed in the board 10, in the same number as the through-holes 13. The connection terminals 65 are made of, for example, a tin- or nickel-plated copper alloy. The plurality of connection terminals 65 are passed through the through-holes 13 formed in the board 10 and are electrically connected to the through-holes 13 via the solder joints 15.

The case 60 is basically formed of a resin-based insulating member such as PPS (polyphenylene sulfide) or PBT (polybutylene terephthalate), but includes a wiring pattern that extends to the outside of the case 60. The plurality of connection terminals 65 are connected to this wiring pattern, so that electrical connection is established between the wiring pattern of the board 10 with the electronic components 20 and 30 mounted thereon and external elements via the connection terminals 65 and the wiring pattern.

The lid 70 is connected to the open end of the case 60, i.e., distal ends of the side walls 62, thereby sealing the case 60. The lid 70 is secured to the case 60 via, for example, an adhesive. In this embodiment, the lid 70 is made of a metal material having high heat conductivity, such as aluminum or copper, and is formed of a rectangular plate-like member.

The heat dissipating gel 80 is disposed between the heat sink 50 and the lid 70 so as to be brought into contact with both the heat sink 50 and the lid 70. Thus, the heat dissipating gel 80 conducts heat from the heat sink 50 to the lid 70. The heat dissipating gel 80 is made of a silicone oil compound having high heat conductivity, for example. Another structure is possible in that the heat dissipating gel 80 is omitted and the heat sink 50 is directly brought into contact with the lid 70. However, it is preferable to provide the freely deformable heat dissipating gel 80, because of the difficulty in adjusting the height of the heat sink 50 and because of the possibility that the lid 70 may press the heat sink 50 when fixedly attached.

The electronic apparatus S1 according to this embodiment is configured as described above. Such an electronic apparatus S1 is produced by the following production method.

First, the board 10 having the wiring pattern, through-holes 13 and the like formed thereon and therein is prepared. The board 10 is produced as follows. The core layer 10a having the metal layers on both the surfaces for forming the inner wiring layers, for example, is prepared, the through-holes are formed in the metal layers and the core layer 10a with the use of a drill or the like, and the insides of the through-holes are plated with metal to form through-hole electrodes. Next, the metal layers are subjected to patterning to form the inner wiring layers. The through-holes 13 are formed at this time by the through-hole electrodes. Furthermore, the buildup layers 10b and the metal layers for forming the surface wiring layers are disposed on both the surfaces of the core layer 10a. Pressure and heat are applied to integrate the core layer 10a with the buildup layers 10b and the metal layers. The metal layers are subjected to patterning to form surface the wiring layers, and then the holes are formed in the buildup layers 10b by laser processing or the like. Thus, the buildup layers 10b are formed with the openings that have a larger inner diameter than the openings in the core layer 10a in portions where the through-holes 13 are formed. Thereafter, the fixture holes 14 are formed by a drilling process or the like using a drill. The board 10 can be produced in this way.

Next, the case 60 provided with the connection terminals 65 is prepared. After the electronic components 20 and 30 are mounted on the first surface 11 of the board 10, the board 10 with the electronic components 20 and 30 mounted thereon is encapsulated in the mold resin 40 by a transfer molding method or a compression molding method. The heat sink 50 is joined to the second surface 12 of the board 10 via the joint member 51, and then the board 10 is placed inside the housing recess 63 of the case 60 such that the first surface 11, i.e., the surface on which the electronic components 20 and 30 are mounted and the mold resin 40 is disposed faces the bottom surface 61. At this time, the plurality of connection terminals 65 are inserted into the through-holes 13, and the distal ends of the mechanical connection parts 64 are fitted into the fixture holes 14.

Thereafter, the distal ends of the mechanical connection parts 64 are heat-staked, and the through-holes 13 and the plurality of connection terminals 65 are connected via the solder joints 15. At this time, in the portions where the through-holes 13 are formed, the size of the openings in both buildup layers 10b is made larger than the size of the opening in the core layer 10a. Therefore, the solder joints 15 are joined only to the core layer 10a, but are not to the buildup layers 10b.

Finally, the heat dissipating gel 80 is disposed on the surface of the heat sink 50, the lid 70 is placed thereon, and the lid 70 is secured to the side walls 62 of the case 60 with an adhesive or the like, whereby the electronic apparatus S1 according to this embodiment is complete.

In the electronic apparatus according to this embodiment described above, the surface on which the electronic components 20 and 30 are mounted and the mold resin 40 is disposed is oriented to face the bottom surface 61 of the case 60 on which the connection terminals 65 are erected. The board 10 is housed inside the housing recess 63 such that the mold resin 40 is situated between the distal end position and the proximal end position of the connection terminals 65. That is, the mold resin 40 is disposed inside the space formed by the height of the connection terminals 65 between the board 10 and the bottom surface 61. Thus, no dead space by the height of the mold resin 40 is formed. The electronic apparatus can thus have a structure that enables a reduction in size. Moreover, a certain length for the connection terminals 65 can also be secured, so that stress applied to connections between the connection terminals 65 and the through-holes 13 can be reduced, and connection reliability can be secured.

In other words, the case 60 and the board 10 are made of different materials and have different thermal expansion coefficients. Moreover, the case 60 and the board 10 are mechanically fixed to each other via portions other than the through-holes 13, for example, via the heat-staked portions at the distal ends of the mechanical connection parts 64 and other through-holes. Therefore, the through-holes 13 may be displaced relative to the case 60 because of a difference in thermal expansion coefficient between the case 60 and the board 10 and the connections of the through-holes 13 may be subjected to stress. However, the longer the connection terminals 65 are, the more easily the connection terminals 65 can flex. Therefore, even if the through-holes 13 are displaced relative to the case 60, the stress that may be excessively applied to the connections of the through-holes 13 can be reduced through deflection of the connection terminals 65.

Moreover, in the portions where the through-holes 13 are formed, the size of the openings in both buildup layers 10b is made larger than the size of the opening in the core layer 10a. Therefore, the solder joints 15 that join the through-holes 13 with the connection terminals 65 are joined only to the core layer 10a, but are not joined to the buildup layers 10b. That is, the connecting length between the solder joints 15 and the board 10 along the axial direction of the connection terminals 65 can be made shorter.

Therefore, the portion of the board 10 where the through-holes 13 are formed has a structure with reduced displacement such that the amount of thermal expansion and contraction in the thickness direction of the board 10 is smaller as compared to portions other than the through-holes 13. Accordingly, the stress along the axial direction of the connection terminals 65 caused by the difference in thermal expansion coefficient between the solder joints 15 in the through-holes 13 and the board 10 can be mitigated. Thus, without having to perform a process step for forming curved portions on the connection terminals 65, the stress applied to the solder joints 15 between the connection terminals 65 and the through-holes 13 in the board 10 can be mitigated, and damage to the solder joints 15 can be reduced.

### Second Embodiment

A second embodiment of the present disclosure will be described. This embodiment has a structure with reduced displacement in the through-holes 13 modified from that of the first embodiment. Since other features are the same as those of the first embodiment, parts that are different from the first embodiment only will be described.

As shown in FIG. 4, in this embodiment, the through-holes 13 are provided with a stress-relaxation member 10c made of a material having a lower thermal expansion coefficient than those of the constituent materials for the core layer 10a and buildup layers 10b inside the openings that form the through-holes 13 in the core layer 10a and buildup layers 10b. The openings in the core layer 10a and the buildup layers 10b have the equal size. The stress-relaxation member 10c is formed to cover the surfaces of the openings while leaving an opening for the connection terminal 65 to pass through. The through-holes 13 are configured by metal-plating the surface of this stress-relaxation member 10c and the open ends of the core layer 10a and the buildup layers 10b. Any material is applicable as the constituent material for the stress-relaxation member 10c as long as it has a lower thermal expansion coefficient than those of the constituent materials for the core layer 10a and the buildup layers 10b. A non-conductive copper paste or the like used as a material for filling blind via holes, for example, may be applied.

As described above, the stress-relaxation member 10c is provided inside the openings that form the through-holes 13 in the core layer 10a and the buildup layers 10b. In such a configuration, the stress-relaxation member 10c forms a structure with reduced displacement such that thermal expansion and contraction occur to a lesser extent than in the core layer 10a and the buildup layers 10b. Therefore, the stress along the axial direction of the connection terminals 65 caused by the difference in thermal expansion coefficient between the solder joints 15 in the through-holes 13 and the board 10 can be mitigated. Accordingly, the same effects as those of the first embodiment can be achieved.

The production method of the board 10 in such an electronic apparatus is basically similar to that of the first embodiment, but the step of forming the stress-relaxation member 10c and the metal-plating step for forming the through-holes 13 are different from those of the first embodiment. For example, the core layer 10a, buildup layers 10b, and the metal layers for forming surface wiring layers are first integrated, and then drilling is performed by laser processing on the core layer 10a, buildup layers 10b, and metal layers. Thus, openings are formed in the core layer 10a and the buildup layers 10b at positions where the through-holes 13 are to be formed. The stress-relaxation member 10c is then provided on the inner walls of the openings in the core layer 10a and the buildup layers 10b. For example, the openings in the core layer 10a and the buildup layers 10b are first filled with the stress-relaxation member 10c, and then an opening is formed in the stress-relaxation member 10c by laser processing. Thus, the tubular stress-relaxation member 10c is formed. Metal-plating is then performed to form the through-holes 13. The board 10 provided in the electronic apparatus of this embodiment can be produced through these steps.

### Third Embodiment

A third embodiment of the present disclosure will be described. This embodiment has a structure with reduced displacement in through-holes 13 modified from that of the first embodiment. Since other features are the same as those of the first embodiment, parts that are different from the first embodiment only will be described.

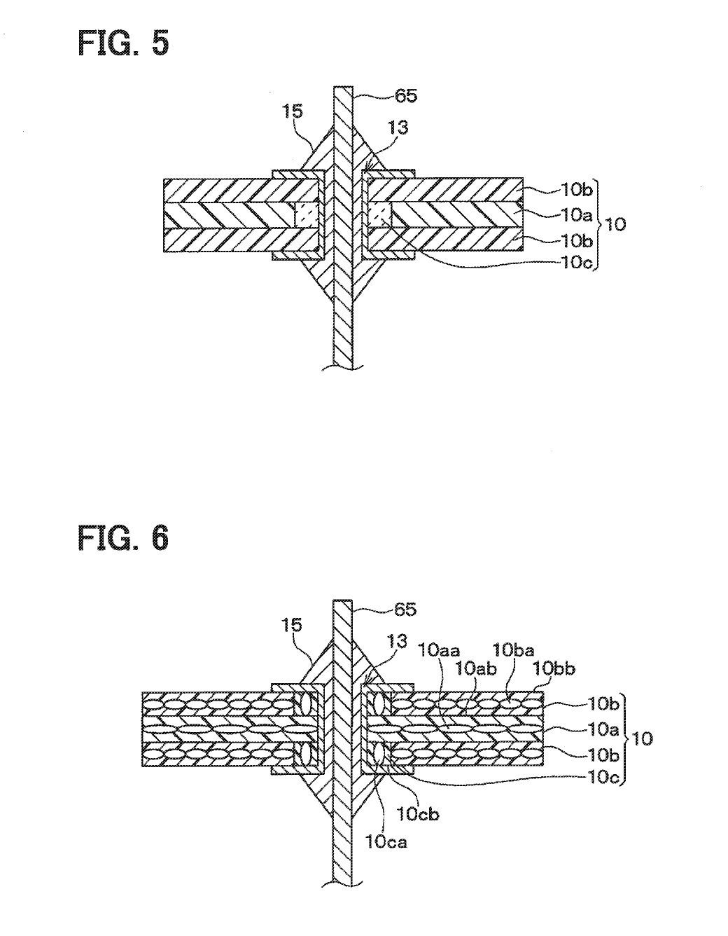

As shown in FIG. 5, in this embodiment, in the portion where the through-holes 13 are formed, the size of the opening in the core layer 10a is made larger than the size of the openings in the buildup layers 10b. The stress-relaxation member 10c made of a material having a lower thermal expansion coefficient than that of the constituent material for the core layer 10a is provided inside the opening in the core layer 10a, similarly to the second embodiment. The through-holes 13 are configured by metal-plating the inner walls of the stress-relaxation member 10c and the buildup layers 10b, and the open ends of the buildup layers 10b.

As described above, the stress-relaxation member 10c is provided inside the openings that form the through-holes 13 of the core layer 10a. In such a configuration, the stress-relaxation member 10c forms the structure with reduced displacement such that thermal expansion and contraction occur to a lesser extent than in the core layer 10a. Therefore, the stress along the axial direction of the connection terminals 65 caused by the difference in thermal expansion coefficient between the solder joints 15 in the through-holes 13 and the board 10 can be mitigated. Accordingly, the same effects as those of the first embodiment can be achieved.

The production method of the board 10 in such an electronic apparatus is also basically similar to that of the first embodiment, but the step of forming the stress-relaxation member 10c and the metal-plating step for forming the through-holes 13 are different from those of the first embodiment. For example, before integrating the core layer 10a, buildup layers 10b, and metal layers for forming surface wiring layers, openings are formed in advance in the core layer 10a in the portions where the through-holes 13 are to be formed, and the openings are filled with the stress-relaxation member 10c. The core layer 10a, buildup layers 10b, and metal layers for forming surface wiring layers are then integrated. Thereafter, drilling is performed on the buildup layers 10b and metal layers, as well as to the stress-relaxation member 10c, by laser processing. Thus, openings are formed in the buildup layers 10b and the stress-relaxation member 10c at positions where the through-holes 13 are to be formed. Thereafter, metal-plating is performed to form the through-holes 13. The board 10 provided in the electronic apparatus of this embodiment can be produced through these steps.

### Fourth Embodiment

A fourth embodiment of the present disclosure will be described. This embodiment has a structure for through-holes 13 modified from that of the first embodiment. Since other features are the same as those of the first embodiment, parts that are different from the first embodiment only will be described.

As shown in FIG. 6, in this embodiment, in the portion where the through-holes 13 are formed, the size of the openings in the buildup layers 10b is made larger than the size of the opening in the core layer 10a. The openings in the buildup layers 10b are filled with the stress-relaxation member 10c that contains a glass cloth 10ca and a resin 10cb. The glass cloth 10ca is oriented such that its longitudinal direction coincides with a normal direction relative to the plane of the board 10.

As shown in FIG. 6, the core layer 10a and the buildup layers 10b are also formed by prepregs, which are a film-like glass cloth 10aa or 10ba made of woven glass fiber and sealed with a thermoplastic resin 10ab or 10bb on both surfaces. However, the longitudinal direction of the glass fiber forming the glass cloth 10aa or 10ba is parallel to the plane direction of the board 10. In such a structure, while the thermal expansion coefficient is small along the plane direction of the board 10 parallel to the longitudinal direction of the glass fiber that forms the glass cloth 10aa or 10ba, the thermal expansion coefficient is larger along the normal direction of the board 10 because of the presence of the resins 10ab and 10bb.

On the other hand, in the stress-relaxation member 10c disposed inside the openings of the buildup layers 10b, the glass cloth 10ca is oriented such that the longitudinal direction of the constituent glass fiber coincides with the normal line relative to the plane of the board 10. Therefore, in the portion where the stress-relaxation member 10c is disposed, the thermal expansion coefficient is lower along the longitudinal direction of the glass cloth 10ca, i.e., the normal direction relative to the plane of the board 10, in other words, along the axial direction of the connection terminal 65, than that in the plane direction of the board 10.

Accordingly, the structure with reduced displacement such that the extent of thermal expansion and contraction along the axial direction of the connection terminals 65 is reduced can be formed by disposing the stress-relaxation member 10c inside the openings of the buildup layers 10b and by disposing the glass cloth 10ca in a different orientation from those of the core layer 10a and the buildup layers 10b. Therefore, the stress along the axial direction of the connection terminals 65 caused by the difference in thermal expansion coefficient between the solder joints 15 in the through-holes 13 and the board 10 can be mitigated, and the same effects as those of the first embodiment can be achieved.

The production method of the board 10 in such an electronic apparatus is also basically similar to that of the first embodiment, but the step of forming the stress-relaxation member 10c and the metal-plating step for forming the through-holes 13 are different from those of the first embodiment.

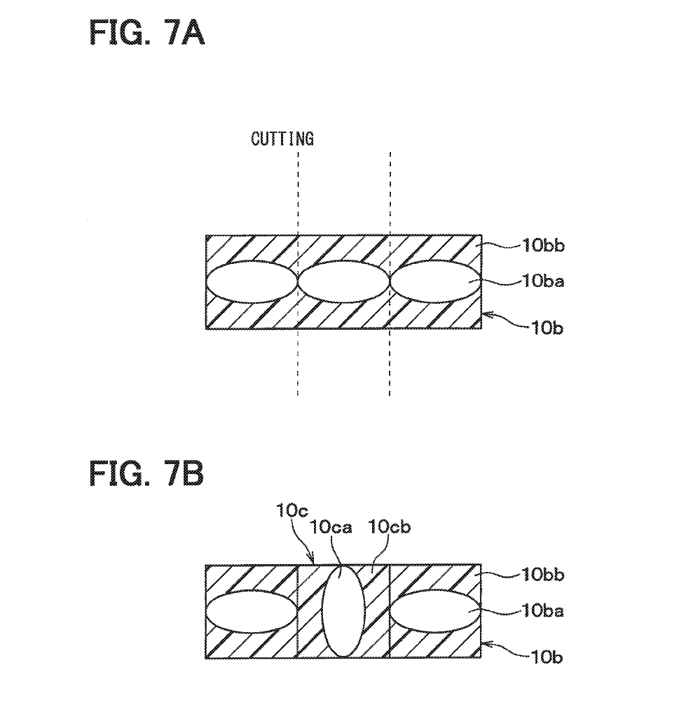

For example, before integrating the buildup layers 10b with the core layer 10a or after the integration, portions of the buildup layers 10b corresponding to the through-hole 13 are punched out, as shown in FIG. 7A. Each punched-out portion is used as the stress-relaxation member 10c, by rotating the punched-out portion by 90 degrees and putting it back to fill the punched-out opening as shown in FIG. 7B. Thereafter, drilling is performed on the core layer 10a and the stress-relaxation member 10c by laser processing. Thus, openings are formed in the core layer 10a and the stress-relaxation member 10c at positions where the through-holes 13 are to be formed. Thereafter, metal-plating is performed to form the through-holes 13. The board 10 provided in the electronic apparatus of this embodiment can be produced through these steps.

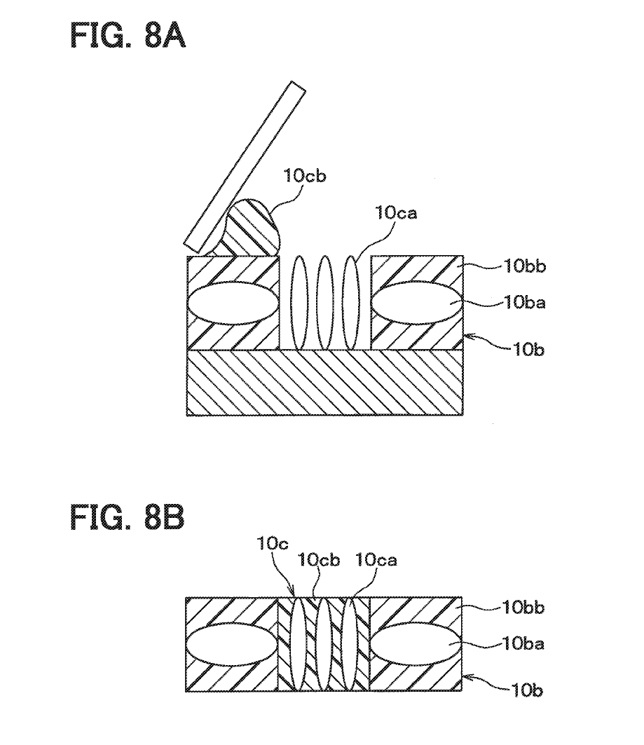

Alternatively, before integrating the buildup layers 10b with the core layer 10a or after the integration, portions of the buildup layers 10b corresponding to the through-holes 13 are punched out, as shown in FIG. 8A. A bundle of glass cloth 10ca is disposed in each punched-out opening. The punched-out opening is then filled with the resin 10cb, whereby the stress-relaxation member 10c is formed, as shown in FIG. 8B. Thereafter, process steps after those of FIGS. 7A and 7B may be performed, whereby the board 10 provided in the electronic apparatus of this embodiment can be produced.

### Fifth Embodiment

A fifth embodiment of this disclosure will be described. This embodiment has a structure for through-holes 13 modified from that of the first embodiment. Since other features are the same as those of the first embodiment, parts that are different from the first embodiment only will be described.

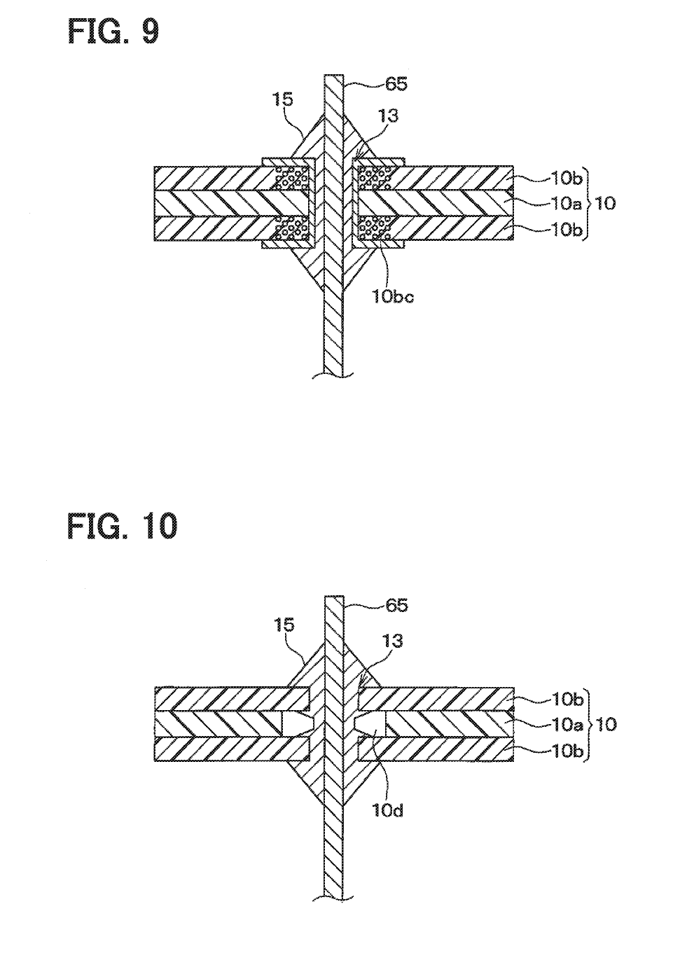

As shown in FIG. 9, in this embodiment, in the portions where the through-holes 13 are formed, voids 10bc are formed intentionally in inner was around the openings in the buildup layers 10b. By forming the voids 10bc around the openings in the buildup layers 10b, the buildup layers 10b can have lower coefficient of elasticity and can be made softer in the portions where the through-holes 13 are formed.

In this way, an elastic deformable structure such that the board 10 has a lower coefficient of elasticity in its thickness direction is provided in the portions where the through-holes 13 are formed by forming the voids 10bc around the openings in the buildup layers 10b. Therefore, the stress caused by the difference in thermal expansion coefficient between the solder joints 15 and the board 10 can be mitigated based on the deformation of the buildup layers 10b. Accordingly, by providing such an elastic deformable structure, the same effects as those of the first embodiment can be achieved.

To form the voids 10bc in the buildup layers 10b, for example, the portions of the resin 10bb that sandwich the glass cloth 10ba may be given a reduced filling rate in the portions where the through-holes 13 are to be formed.

### Sixth Embodiment

A sixth embodiment of the present disclosure will be described. This embodiment has an elastic deformable structure in through-holes 13 modified from that of the fifth embodiment. Since other features are the same as those of the first embodiment, parts that are different from the first embodiment only will be described.

As shown in FIG. 10, in this embodiment, in the portions where the through-holes 13 are formed, the size of the opening in the core layer 10a is made larger than the size of the openings in both the buildup layers 10b. The through-holes 13 are configured by metal-plating the inner walls and open ends of the buildup layers 10b, so that the solder joints 15 are joined only to the buildup layers 10b, but are not joined to the core layer 10a.

In such a structure, in the portions where the through-holes 13 are formed, gaps 10d are formed between the buildup layers 10b. The buildup layers 10b have a lowered coefficient of elasticity and are softer in these portions, i.e., an elastic deformable structure is formed which allows the connection terminals 65 to displace along their axial direction. Therefore, the stress caused by the difference in thermal expansion coefficient between the solder joints 15 and the board 10 can be mitigated based on the deformation of the buildup layers 10b. Accordingly, by providing such a structure, the same effects as those of the first embodiment can be achieved.

The board 10 having such a structure can be produced by a production method that is basically the same as that of the first embodiment and the like. A step of forming openings in the core layer 10a in the portions where the through-holes 13 are to be formed may be performed before integrating the core layer 10a and the buildup layers 10b.

### Seventh Embodiment

A seventh embodiment of the present disclosure will be described. This embodiment has a configuration of a board 10 and the like modified from that of the first embodiment. Since other features are the same as those of the first embodiment, parts that are different from the first embodiment only will be described.

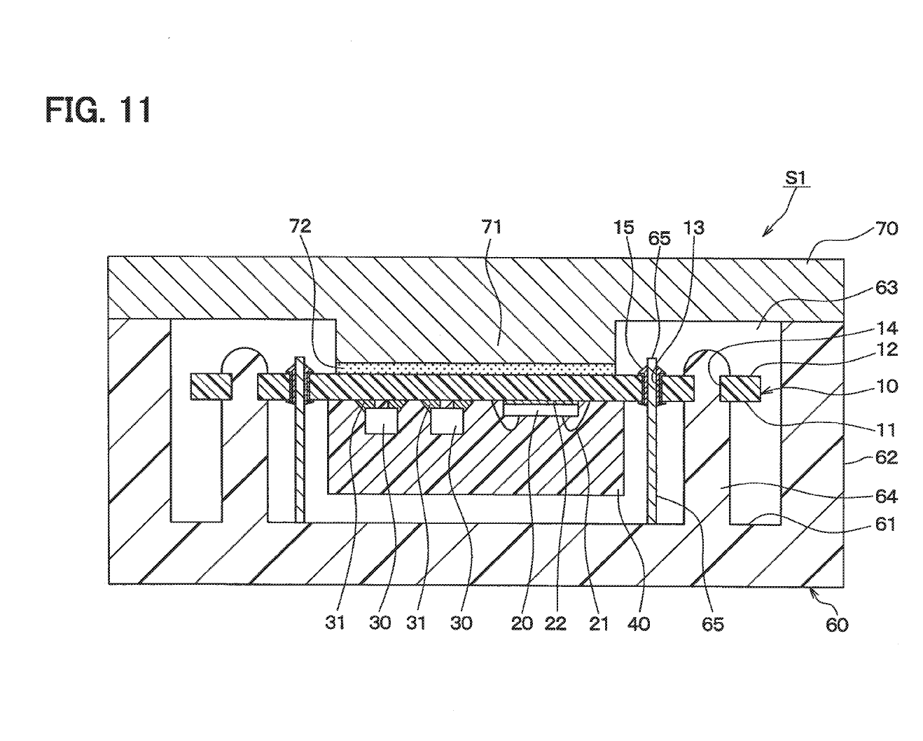

As shown in FIG. 11, in this embodiment, the board 10 has a common structure for the through-holes 13 that does not take account of the stress applied to the solder joints 15 between the through-holes 13 and the connection terminals 65. Although the board 10 is shown as if it has a single layer structure in FIG. 11, it is actually configured to include the core layer 10a and the buildup layers 10b as with the first embodiment and others. The board 10 can of course be configured as a single layer structure.

Also, in this embodiment, the structure in that the heat sink 50 is brought into contact with the lid 70 via the heat dissipating gel 80, as in the first embodiment, is changed. More specifically, in this embodiment, the lid 70 has a protrusion 71 that is partially protruded toward the board 10 on one side facing the board 10, and the protrusion 71 is brought into contact with the second surface 12 of the board 10 via a heat dissipating material 72 made of a heat dissipating gel or the like.

As described above, even in the common structure for the through-holes 13 that does not take account of the stress applied to the solder joints 15 in contrast to the first embodiment, a reduction in size of the electronic apparatus can be achieved by orienting the surface on which the electronic components 20 and 30 are mounted so as to face the bottom surface 61 of the case 60.

Also, by providing the structure, as in this embodiment, in that the lid 70 includes the protrusion 71 and the protrusion 71 is brought into contact with the second surface 12 of the board 10 via the heat dissipating material 72, a reduction in the number of components can be achieved as compared to the first embodiment, whereby a cost reduction in the production of the electronic apparatus can be achieved.

### Eighth Embodiment

An eighth embodiment of the present disclosure will be described. This embodiment has a configuration of connection terminals 65 modified from that of the seventh embodiment. Since other features are the same as those of the seventh embodiment, parts that are different from the seventh embodiment only will be described.

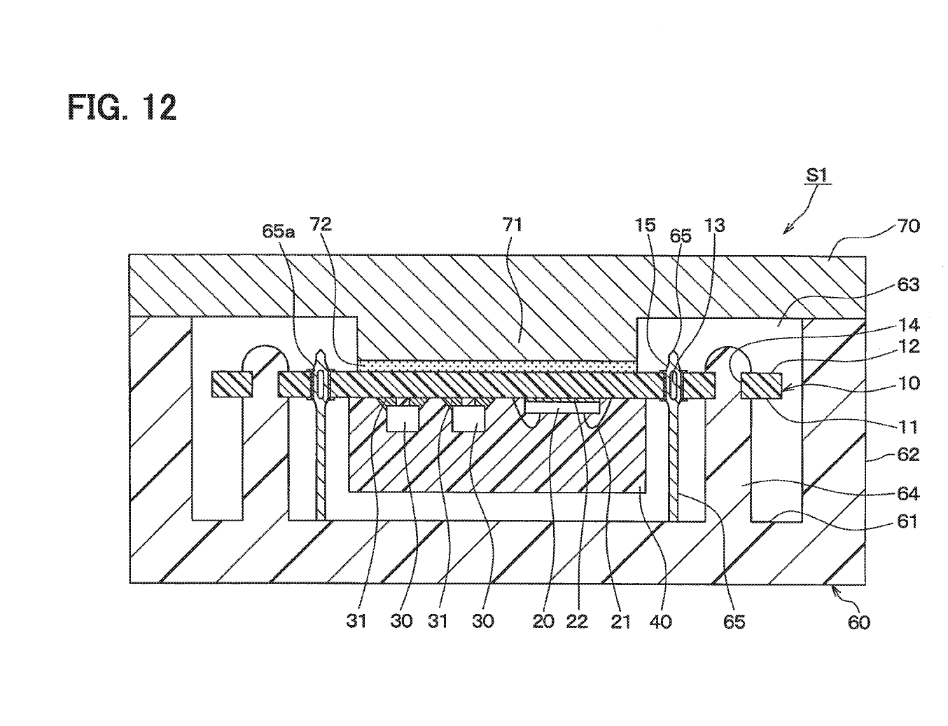

As shown in FIG. 12, in this embodiment, each of the connection terminals 65 is provided with a wide portion 65a larger than the opening size of the through-holes 13 in the portion where the connection terminals 65 are electrically connected to the through-holes 13. When the distal ends of the connection terminals 65 are fitted into the through-holes 13, the inner walls of the through-holes 13 and the wide portions 65a are brought into contact with each other by a press-fit, whereby the electrical connection between the inner walls of the through-holes 13 and the wide portions 65a is established.

As described above, the structure of the seventh embodiment can be applied in such a form that electrical connection is established between the through-holes 13 and the connection terminals 65 by the press-fit instead of the electrical connection via the solder joints 15. By providing such a structure, the same effects as those of the seventh embodiment can be achieved.

### Modifications

The present disclosure is not limited to the embodiments described above, but may be applicable to various other embodiments without departing from the subject matter of the disclosure. The following modifications or extensions are possible, for example.

For example, each of the foregoing embodiments describes one example of the electronic apparatus S1 having, applied thereto, the form in which the electronic components 20 and 30 are mounted on the first surface 11 of the board 10 and then are resin-encapsulated in the mold resin 40. However, this structure need not necessarily be those described in the foregoing embodiments. For example, the first surface 11 of the board 10, i.e., the mold resin 10 is oriented to face the bottom surface 61 of the case 60; however, the second surface 12, i.e., the opposite side to the mold resin 40 may be oriented to face the bottom surface 61.

The technique of retaining the board 10 with the mechanical connection parts 64 is not limited to heat-staking and may be press-fitting or screw-fastening.

Moreover, each of the foregoing embodiments describes the form in which the connection terminals 65 erected on the case 60 are inserted into and connected to the through-holes 13 formed in the board 10; however, the form is also applicable to the case where the connection terminals 65 are connected to the through-holes 13 in a structure in that the connection terminals 65 are erected on another board or the like.

Each of the foregoing embodiments also describe the structure in that one buildup layer 10b is disposed on each of both the sides of the core layer 10a in the board 10; however, the plurality of buildup layers 10b may be disposed on each of both the sides of the core layer 10a.

Moreover, the structures in the respective embodiment can also be varied. For example, in the second embodiment, the stress-relaxation member 10c is formed on the inner walls of the openings in both of the core layer 10a and the buildup layers 10b. On the other hand, in the third embodiment, the stress-relaxation member 10c is formed on the inner wall of the opening in only the core layer 10a; however, the stress-relaxation member 10c may be formed on the inner walls of the openings in only the buildup layers 10b. In the fourth embodiment, also, the stress-relaxation layer 10c is provided in the openings in the buildup layers 10b; however, the stress-relaxation layer 10c may be formed on the inner walls of the openings in both of the core layer 10a and the buildup layers 10b. Alternatively the stress-relaxation layer 10c may be formed on the inner walls of the openings in only the core layer 10a. This applies also to the fifth embodiment. The voids 10bc are formed only in the buildup layers 10b; however, the voids 10bc may be formed in both of the core layer 10a and the buildup layers 10b. Alternatively, the voids 10bc may be formed only in the core layer 10a.

1. An electronic apparatus comprising:
a board having:
a first surface,
a second surface opposite to the first surface,
a wiring pattern formed on the board, and
a through-hole formed in the board and having a metal member connected to the wiring pattern;
an electronic component mounted on the first surface of the board;
a mold resin sealing the electronic component on the first surface of the board;
a rod-like connection terminal inserted into the through-hole from a distal end of the rod-like connection terminal and electrically connected to the metal member in the through-hole; and
a case having a surface on which the rod-like connection terminal stands and accommodating the board on which the electronic component is mounted, wherein:
the board is arranged such that the first surface on which the electronic component and the mold resin are arranged faces the surface of the case on which the rod-like connection terminal stands, and a heat dissipating path is arranged at the second surface opposite to the first surface of the board on which the electronic component and the mold resin are arranged; and
the metal member and the rod-like connection terminal are connected at an outer side of the electronic component and the mold resin as well as an outer side of the heat dissipating path.

2. The electronic apparatus according to claim 1,
wherein the mold resin is housed inside the case so as to be arranged between a distal end position of the rod-like connection terminal and a proximal end position of the rod-like connection terminal.

3. The electronic apparatus according to claim 1,
wherein the distal end of the rod-like connection terminal is electrically connected to the metal member in the through-hole via a solder joint.

4. The electronic apparatus according to 1, wherein:
the rod-like connection terminal has a wide portion at the distal end of the rod-like connection terminal, the wide portion having a larger size than an opening size of the through-hole; and
the rod-like connection terminal is fitted into the through-hole from the distal end of the rod-like connection terminal and the wide portion is electrically connected by a press-fit to the metal member in the through-hole.

5. The electronic apparatus according to claim 1,
wherein the board has, in a portion of the board where the through-hole is formed, a displacement reducing structure such that an amount of thermal expansion and contraction of the displacement reducing structure in a thickness direction of the board is smaller as compared to a portion of the board other than the through-hole.

6. (canceled)

7. The electronic apparatus according to claim 5, wherein:
the board is configured to include a core layer and a buildup layer arranged on both sides of the core layer; and
the displacement reducing structure in the portion of the board where the through-hole is formed is configured such that an opening size of the buildup layer is larger than an opening size of the core layer, and a solder joint that bonds the rod-like connection terminal and the metal member in the through-hole is bonded to the metal member of the through-hole formed in the core layer.

8. The electronic apparatus according to claim 5, wherein:
the board is configured to include a core layer and a buildup layer arranged on both sides of the core layer; and
the displacement reducing structure in the portion of the board where the through-hole is formed is configured by including a stress-relaxation member on an inner wall of an opening formed in the core layer and the buildup layer, the stress-relaxation member made of a material lower in thermal expansion coefficient than a material of the core layer and the buildup layer.

9. The electronic apparatus according to claim 5, wherein:
the board is configured to include a core layer and a buildup layer disposed on both sides of the core layer; and
the displacement reducing structure in the portion of the board where the through-hole is formed is configured such that an opening size of the core layer is larger than an opening size of the buildup layer, and a stress-relaxation member made of a material lower in thermal expansion coefficient than a material for the core layer is arranged on an inner wall of an opening in the core layer.

10. The electronic apparatus according to claim 5, wherein:
the board includes a core layer and a buildup layer made of a prepreg having a film-like glass cloth made of woven glass fiber and sealed with a resin on both sides of the film-like glass cloth, the buildup layer arranged on both sides of the core layer; and
the displacement reducing structure in the portion of the board where the through-hole is formed is arranged inside an opening of at least one of the core layer and the buildup layer, and is configured by arranging a glass cloth having glass fiber oriented such that a longitudinal direction of glass fiber is directed to a normal direction relative to a plane of the board, and a resin with the glass cloth arranged inside the opening.

11. The electronic apparatus according to claim 1, wherein:
the board has, in a portion of the board where the through-hole is formed, an elastic deformable structure such that the elastic deformable structure has a lower coefficient of elasticity in a thickness direction of the board as compared to a portion other than the through-hole.

12. An electronic apparatus comprising:
a board having:
a first surface,
a second surface opposite to the first surface,
a wiring pattern formed on the board, and
a through-hole formed in the board and having a metal member connected to the wiring pattern;
an electronic component mounted on the first surface of the board;
a mold resin sealing the electronic component on the first surface of the board;
a rod-like connection terminal inserted into the through-hole from a distal end of the rod-like connection terminal and electrically connected to the metal member in the through-hole via a solder joint; and
a case having a surface on which the rod-like connection terminal stands and accommodating the board on which the electronic component is mounted, wherein:
the board is arranged such that the first surface on which the electronic component and the mold resin are arranged faces the surface of the case on which the rod-like connection terminal stands; and
the board has, in a portion of the board where the through-hole is formed, an elastic deformable structure such that the elastic deformable structure has a lower coefficient of elasticity in a thickness direction of the board as compared to a portion other than the through-hole.

13. The electronic apparatus according to claim 11, wherein:
the board is configured to include a core layer and a buildup layer arranged on both sides of the core layer; and
the elastic deformable structure in the portion of the board where the through-hole is formed is configured by arranging a void in an inner wall of an opening of at least one of the core layer and the buildup layer.

14. The electronic apparatus according to claim 11, wherein:
the board is configured to include a core layer and a buildup layer arranged on both sides of the core layer, and
the elastic deformable structure in the portion of the board where the through-hole is formed is configured such that an opening size of the core layer is larger than an opening size of the buildup layer, and the solder joint that bonds the rod-like connection terminal and the metal member in the through-hole is bonded to the metal member in the through-hole only formed in the buildup layer.
